(19) United States
(12) Patent Application Publication
(10) Pub. No.: US 2012/0269960 A1
(43) Pub. Date: Oct. 25, 2012

(54) METHOD OF MANUFACTURING CONDUCTIVE LAMINATED FILM

(75) Inventors: Nozomi Fujino, Ibaraki-shi (JP); Kuniaki Ishibashi, Ibaraki-shi (JP); Yoshimasa Sakata, Ibaraki-shi (JP)

(73) Assignee: NITTO DENKO CORPORATION, Osaka (JP)

(21) Appl. No.: 13/450,656

(22) Filed: Apr. 19, 2012

(30) Foreign Application Priority Data
Apr. 20, 2011 (JP) 2011-094261
Feb. 23, 2012 (JP) 2012-037522

(51) Int. Cl. C23C 16/06; C23C 14/34

(52) U.S. Cl. 427/109; 204/192.1

(57) ABSTRACT

A manufacturing method of a conductive laminated film suppressing a wrinkle has a metal layer forming step in which a conductive metal layer is continuously formed on a surface of a long transparent conductive film where a transparent conductive layer is formed while the transparent conductive film, including a long transparent film base containing a polyester resin as a constituting material and the transparent conductive layer formed thereon, is transported. The metal layer forming step is performed under a reduced pressure atmosphere of 1 Pa or less. The long transparent conductive film is continuously transported by application of a transport tensile force, and the conductive metal layer is continuously deposited on the surface where the transparent conductive layer is formed in a state in which a surface where the transparent conductive layer is not formed contacts the surface of a film-forming roll.

### BACKGROUND OF THE INVENTION

1. Field of the Invention

The present invention relates to a method of manufacturing a conductive laminated film including a transparent conductive layer and a conductive metal layer on a transparent base.

2. Description of the Related Art

A transparent electrode made of a transparent conductive oxide such as an indium-tin oxide (ITO) has been used in display devices such as flat panel displays such as a liquid crystal display, a plasma display and an organic EL display, and touch panels. A pattern wiring is connected to the transparent electrode to apply a voltage externally or to detect a potential thereon. A pattern wiring which is formed with a silver paste by a screen printing method or the like is widely used. Generally, a wiring is patterned in a display device so as to wire in a peripheral part around a transparent electrode therein as schematically shown in FIG. 4, for example. A display device is assembled so that the wiring should not be visible from outside by using a decorated base or the like.

There is a tendency that the pattern of the wiring becomes complicated as high-resolution and highly-functional display devices are manufactured. For example, a projection capacitance type touch panel and a matrix resistive film type touch panel capable of multipoint input (multi touch) have been attracting attention recently. In these types of touch panels, a transparent conductive layer is patterned into a prescribed shape such as a rectangle shape to form a transparent electrode, and a pattern wiring is formed between each transparent electrode and a control means such as an IC. While the wiring pattern is becoming more complicated, it has been desired to further narrow a region of which peripheral part is decorated to make the wiring invisible in order to increase the area ratio of a display region in the display device (narrowing of a frame). However, it is difficult to make the frame of the display device narrower because there is a limitation in making the line width of the electrode small.

In order to make the frame of the display device even narrower, it is necessary to use a wiring material having high conductivity to make the pattern wiring thinner and to suppress an increase in the resistance. From such a viewpoint, Japanese Patent Application Laid-Open No. 63-113585 proposes a method of forming a transparent conductive layer on a transparent base, producing a laminated body including the transparent conductive layer and a conductive metal layer formed thereon, and selectively removing the metal layer and the transparent conductive layer sequentially by etching to form a pattern. Because a pattern wiring can be formed by etching in accordance with such a method, the wiring can be made thinner and the frame of the display device can be made narrower compared with a pattern wiring formed by a screen printing method or the like as described above.

In production of the laminated body wherein a transparent conductive layer and a conductive metal layer are formed on a transparent base as described above, the metal layer and the like are generally formed by a vacuum film-forming method such as a sputtering method. When the metal layer is formed continuously on a long base by a roll-to-roll method, forming a film is conducted on a film-forming roll that has been cooled by, for example, a method of circulating a coolant in a vacuum film-forming apparatus to suppress the generation of wrinkles caused by thermal deformation of the film base (for example, Japanese Patent Application Laid-Open No. 62-247073).

### SUMMARY OF THE INVENTION

When the metal layer is formed on the film base as described above, the thermal deformation is prevented by cooling the film base. However, it was revealed that wrinkles can be easily formed on the film base even if the film-forming roll is cooled when a transparent conductive layer is formed on a transparent film base and a metal layer is further formed thereon. From such a point of view, an object of the present invention is to provide a method of manufacturing a conductive laminated film in which generation of wrinkles is suppressed.

The present invention relates to a method of manufacturing a conductive laminated film in which a transparent conductive layer made of a conductive metal oxide and a conductive metal layer are formed sequentially on a transparent film base containing a polyester resin as a constituting material. In the manufacturing method of the present invention, a conductive metal layer is continuously formed on a surface of along transparent conductive film where a transparent conductive layer is formed while the long transparent conductive film including a long transparent film base and the transparent conductive layer formed thereon is transported. The conductive metal layer is formed under a reduced pressure atmosphere of 1 Pa or less. The long transparent conductive film is continuously transported by application of a transport tensile force, and the conductive metal layer is continuously deposited on the surface where the transparent conductive layer is formed in a state in which a surface of the transparent conductive film where the transparent conductive layer is not formed contacts the surface of a film-forming roll. The surface temperature of the film-forming roll is preferably 110 to 200° C. The transport tensile force per unit area in a plane perpendicular to the longitudinal direction of the film base in a region where the film is formed is preferably 0.6 to 1.8 N/mm².

The transport tensile force per unit width is preferably applied so as to satisfy the following formula wherein x (mm) represents the thickness of the film base in a region where the film is formed and y (N/mm) represents the transport tensile force per unit width:

0.6x≦y≦1.8x.

The conductive metal layer is preferably formed by a sputtering method. The deposition thickness of the conductive metal layer is preferably 20 nm or more.

The transparent conductive layer is preferably a conductive oxide layer containing an indium-tin oxide as a main component. The conductive metal layer is preferably made of one type or two types or more of metals selected from the group consisting of Ti, Si, Nb, In, Zn, Sn, Au, Ag, Cu, Al, Co, Cr, Ni, Pb, Pd, Pt, W, Zr, Ta, and Hf or an alloy containing these metals as a main component. The conductive metal layer is especially preferably made of copper substantially.

Because the conductive metal layer is formed with a prescribed transport tensile force and under a prescribed temperature condition according to the present invention, generation of wrinkles in formation of the conductive metal layer is suppressed, and the conductive laminated film has an excellent external appearance and excellent in-plane uniformity of the electric characteristics. In the conductive laminated body obtained by the present invention, a transparent conductive laminated film with a pattern wiring can be formed by patterning a portion of the conductive metal layer into a prescribed shape by etching or the like, for example. The transparent conductive film obtained in such a manner can be suitably used in an optical device such as a touch panel and a display device.

### BRIEF DESCRIPTION OF THE DRAWINGS

FIG. 1 is a schematic sectional view of a conductive laminated film according to one embodiment;

FIG. 2 is a schematic sectional view of a conductive laminated film according to one embodiment;

FIG. 3 is a conceptual diagram for explaining a configuration of a vacuum film-forming apparatus;

FIG. 4 is a schematic plan view of a transparent conductive laminated film with a pattern wiring according to one embodiment;

FIG. 5 is a drawing schematically showing a section at the V-V line of FIG. 4; and

FIG. 6 is a schematic plan view for explaining a manufacturing process of a transparent conductive laminated film with a pattern wiring.

### DETAILED DESCRIPTION OF PREFERRED EMBODIMENTS

### <Conductive Laminated Film>

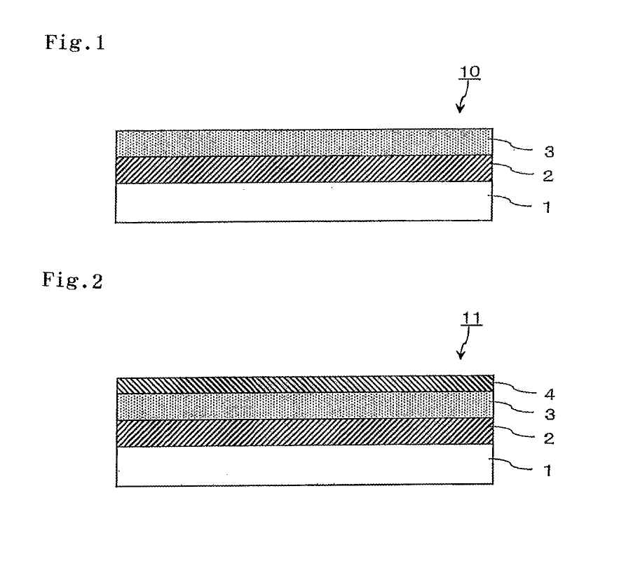

Hereinafter, embodiments of the present invention will be described with reference to the drawings. FIG. 1 is a schematic sectional view of a conductive laminated film according to one embodiment. A conductive laminated film 10 has a configuration in which a transparent conductive layer 2 and a conductive metal layer 2 are laminated sequentially on a transparent film base 1. In the manufacturing method of the present invention, the conductive metal layer 3 is formed on a surface of a long transparent conductive film where the transparent conductive layer 2 is formed on a long transparent film base.

### [Transparent Film Base]

The transparent film base 1 is not especially limited as long as it has flexibility and it is transparent in the visible light region, and a plastic film having transparency and containing a polyester resin as a constituting material can be used. A polyester resin is suitably used because it has excellent transparency, heat resistance, and mechanical characteristics. Polyethylene terephthalate (PET) and polyethylene naphthalate (PEN) are especially suitable as the polyester resin. From the viewpoint of strength, it is preferred that a stretching treatment is performed on the plastic film, and it is more preferred that a biaxial stretching treatment is performed thereon. The stretching treatment is not especially limited, and a known stretching treatment can be adopted.

The thickness of the transparent film substrate is preferably in a range of 2 to 200 μm, more preferably in a range of 2 to 130 μm, and further preferably in a range of 2 to 100 μm. When the thickness of the film is less than 2 μm, the mechanical strength of the transparent film substrate becomes insufficient and the operation of forming the transparent conductive layer 2 and the conductive metal layer 3 successively by making the film substrate into a roll may become difficult. On the other hand, when the thickness of the film exceeds 200 μm, the scratch resistance of the transparent conductive layer 2 and tap property for a touch panel may not be improved.

The surface of the transparent film substrate may be previously subjected to sputtering, corona discharge treatment, flame treatment, ultraviolet irradiation, electron beam irradiation, chemical treatment, etching treatment such as oxidation, or undercoating treatment such that the adhesion of the transparent film substrate to the transparent conductive layer 2 formed on the film substrate can be improved. If necessary, the surface of the film substrate may also be subjected to dust removing or cleaning by solvent cleaning, ultrasonic cleaning or the like, before the transparent conductive layer is formed.

A dielectric layer or a hard coat layer may be formed on the surface of the transparent film base 1 where the transparent conductive layer 2 is formed. The dielectric layer formed on the surface of the transparent base where the transparent conductive layer is formed does not function as a conductive layer, and has a surface resistance of 1×10⁶ Ω/square or more, preferably 1×10⁷ Ω/square or more, more preferably 1×10⁸ Ω/square or more. The surface resistance of the transparent dielectric layer does not have any particular upper limit. While the surface resistance of the transparent dielectric layer may generally has an upper limit of about 1×10¹³ Ω/square, which corresponds to a measuring limit, it may be higher than 1×10¹³ Ω/square.

The materials of the dielectric layer include an inorganic material such as NaF (1.3), Na₃AlF₆ (1.35), LiF (1.36), MgF₂ (1.38), CaF₂ (1.4), BaF₂ (1.3), SiO₂ (1.46), LaF₃ (1.55), CeF₃ (1.63), and Al₂O₃ (1.63), wherein each number inside the parentheses is the refractive index of each material, an organic material such as acrylic resins, urethane resins, melamine resins, alkyd resins, siloxane polymers, and organosilane condensates, which have an refractive index of about 1.4 to 1.6, and a mixture of the inorganic material and the organic material.

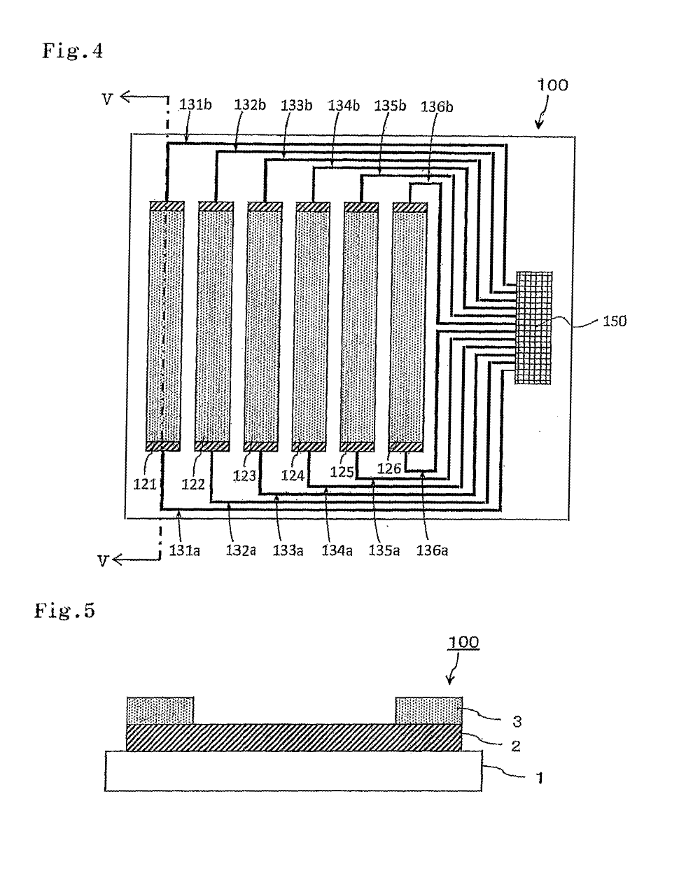

By forming the dielectric layer on the surface of the transparent base where the transparent conductive layer is formed, the difference in visibility between a region where the transparent conductive layer is formed and a region where the transparent conductive layer is not formed can be reduced even when the transparent conductive layer 2 is patterned into a plurality of transparent electrodes 121 to 126 as shown in FIG. 4. When a film base is used as the transparent base, the dielectric layer can also act as a sealing layer that suppresses deposition of low molecular weight components such as an oligomer from a plastic film.

A hard coat layer, an easy adhesion layer, an anti-blocking layer, and the like maybe provided on the surface opposite to the surface of the transparent film base 1 where the transparent conductive layer 2 is formed if necessary. The transparent film base 1 may be a base to which other bases are bonded using an appropriate adhering means such as a pressure-sensitive adhesive or may be a base in which a protective layer such as a separator is temporarily bonded to a pressure-sensitive adhesive layer or the like for bonding the transparent film base 1 to other bases.

The transparent film base is provided in a roll in which a long film is wound, and the transparent conductive layer 2 is continuously formed thereon to give the long transparent conductive film.

### [Transparent Conductive Layer]

Examples of materials that may be used to form the transparent conductive layer 2 are not limited, but oxides of at least one metal selected from the group consisting of In, Sn, Zn, Ga, Sb, Ti, Si, Zr, Mg, Al, Au, Ag, Cu, Pd, and W are preferably used. Such metal oxides maybe optionally added with any metal atom selected from the above group. For example, indium oxide containing tin oxide (ITO) or tin oxide containing antimony (ATO) is preferably used, and ITO is especially preferably used.

The thickness of the transparent conductive layer is not especially limited. However, the thickness is preferably 10 nm or more to make the transparent conductive layer 3 be a continuous film having good conductivity of which surface resistance is 1×10³ W/square or less. When the film thickness is too large, a decrease in transparency, or the like is brought about, and therefore the thickness is preferably 15 to 35 nm and more preferably 20 to 30 nm. When the thickness of the transparent conductive layer is less than 15 nm, the electric resistance of the film surface becomes high and it is difficult to form a continuous film. When the thickness of the transparent conductive layer exceeds 35 nm, a decrease in transparency, or the like may be brought about.

The method of forming the transparent conductive layer is not especially limited, and an appropriate method can be adopted according to materials used for forming the transparent conductive layer and the required film thickness. From the viewpoints of uniformity of the film thickness and film-forming efficiency, vacuum film-forming methods such as a chemical vapor deposition (CVD) method and a physical vapor deposition (PVD) method are suitably adopted. Among these, physical vapor deposition methods such as a vacuum vapor deposition method, a sputtering method, an ion plating method, and an electron beam evaporation method are preferable, and a sputtering method is especially preferable.

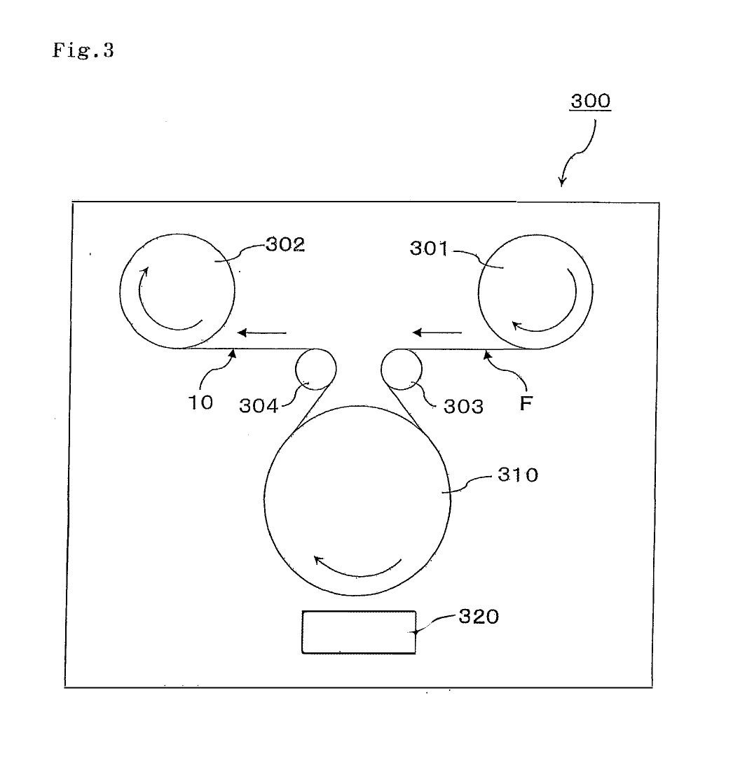

From the viewpoint of obtaining a long laminated body, the transparent conductive layer 2 is preferably formed while transporting the base under a prescribed applied tensile force by a roll-to-roll method or the like, for example. The transparent conductive layer can be formed by the roll-to-roll method by using a winding type sputtering machine 300 as schematically shown in FIG. 3, by performing a sputtering method on a film-forming roll 310 while continuously transporting a film base by sending the base out of an unwinding roll 301, and winding the laminated film including the base 1 and the transparent conducive layer 2 formed thereon into a roll by a winding roll 302.

When an ITO film is formed as the transparent conductive layer 2, a metal target (an In—Sn target) or a metal oxide target (an In₂O₃—SnO₂ target) is suitably used as a sputtering target. When the In₂O₃—SnO₂ metal oxide target is used, the amount of SnO₂ in the metal oxide target is preferably 0.5 to 15% by weight, more preferably 1 to 12% by weight, and further preferably 2 to 10% by weight to the total weight of In₂O₃ and SnO₂. In the case of reactive sputtering in which an In—Sn metal target is used, the amount of Sn atoms in the metal target is preferably 0.5 to 15% by weight, more preferably 1 to 12% by weight, and further preferably 2 to 10% by weight to the total weight of In atoms and Sn atoms. When the amount of Sn or SnO₂ in the target is too small, the durability of the ITO film may deteriorate. When the amount of Sn or SnO₂ is too large, crystallization of the ITO film becomes difficult, and transparency and stability of the resistance value may be insufficient.

In the sputtering film-forming process using such a target, a sputtering machine is preferably vented to a degree of vacuum (ultimate vacuum) of preferably 1×10⁻³ Pa or less and more preferably 1×10⁻⁴ Pa or less to create an atmosphere in which water in the sputtering machine and impurities such as an organic gas generated from the base have been removed. This is because, when there are water and an organic gas in the machine, they terminate dangling bonds generated during a sputtering film-forming process and prevent crystal growth of a conductive oxide such as ITO.

A sputtering film-formation process is performed under a reduced pressure of 1 Pa or less while introducing a reactive gas such as an oxygen gas in the vented sputtering machine as necessary together with an inert gas such as Ar and transporting the base under a prescribed tensile force. The pressure upon forming a film is preferably 0.05 to 1 Pa and more preferably 0.1 to 0.7 Pa. When the pressure for forming a film is too high, the film-forming speed tends to decrease, and when the pressure is too low, discharge tends to become unstable.

The base temperature when ITO is formed into a film by sputtering is preferably 40 to 190° C. and more preferably 80 to 180° C. Because of that, the temperature of the film-forming roll 310 is preferably adjusted in this range. The transport speed of the base when forming a film by sputtering is not especially limited, and it can be appropriately set according to the materials of the transparent conductive layer 2, the thickness of the film to be formed, and the like. The transport tensile force of the base when forming a film by sputtering is not especially limited, and the transport tensile force per unit area in the plane perpendicular to the longitudinal direction of the base is preferably 0.2 to 9.2 N/mm², and more preferably 0.4 to 5.6 N/mm². The transport tensile force per unit width of the base is preferably 0.01 to 0.46 N/mm and more preferably 0.02 to 0.28 N/mm when the thickness of the base is 50 μm. When the transport tensile force of the base is too small, the transportation of the base may become unstable, and when the transport tensile force of the base is too large, the dimension of the base may change.

The above description is an example of forming an ITO film by a sputtering method. Various film-forming conditions can be appropriately set according to the materials of the transparent conductive layer, the film-forming method, the thickness of the film, and the like.

The transparent conductive layer 2 may be crystalline or may be amorphous. Because there is a restriction due to the heat resistance of the base when an ITO film is formed as the transparent conductive layer by a sputtering method, the film cannot be formed by sputtering at a high temperature. Because of that, the ITO film right after being formed is an amorphous film (there is a case where a portion of the film is crystallized). There may be problems that the transmittance of such an amorphous ITO film is small compared with a crystalline ITO film and that a change in resistance after a humidification and heating test is large. From such viewpoints, it may be adopted to form an amorphous transparent conductive layer for the moment, and then heat the layer under the presence of oxygen in the air to transform the transparent conductive layer to a crystalline film. There are advantages by crystallizing the transparent conductive layer that the transparency improves, that the change in resistance after a humidification and heating test is small, and that the reliability to humidification and heating improves.

The crystallization of the transparent conductive layer can be performed either after an amorphous transparent conductive layer 2 is formed on the transparent film base 1, or before or after the conductive metal layer 3 is formed. When a part of the transparent conductive layer 2 is removed to be patterned by etching or the like, the crystallization of the transparent conductive layer may be performed before etching or after etching.

### [Conductive Metal Layer]

The conductive metal layer 3 is continuously formed on the surface of the long transparent conductive film where the transparent conductive layer 2 is formed, thereby giving a long conductive laminated film. The constituting materials of the conductive metal layer are not especially limited as long as they have conductivity, and metals such as Ti, Si, Nb, In, Zn, Sn, Au, Ag, Cu, Al, Co, Cr, Ni, Pb, Pd, Pt, W, Zr, Ta, and Hf can be suitably used. Materials containing two types or more of these metals or alloys containing these metals as a main component can also be suitably used. When a pattern wiring as shown in FIG. 4 is formed by removing a portion of the conductive metal layer 3 by etching or the like after the conductive laminated film is formed, a metal having high conductivity such as Au, Ag, and Cu can be suitably used as the conductive metal layer 3. Among these, Cu is suitable as a material that constitutes the wiring because it has high conductivity and is an inexpensive material. Because of that, it is especially preferred that the conductive metal layer 3 is made of copper substantially.

The thickness of the conductive metal layer 3 is not especially limited. When a pattern wiring is formed by removing a portion of the conductive metal layer 3 by etching or the like after the conductive laminated film is formed, the thickness of the conductive metal layer 3 is appropriately set so that the formed pattern wiring has a desired resistance value. When the thickness of the conductive metal layer is too small, the resistance value of the pattern wiring becomes too large and power consumption of the device may become large. Because of that, the thickness of the conductive metal layer to be deposited is preferably 20 nm or more. When the thickness of the conductive metal layer is too large, productivity becomes poor because long time is required to form the conductive metal layer, the integrated heat quantity during the film-forming process becomes large, and heat wrinkles tend to be easily generated on the film because it is necessary to raise the power density during the film-forming process. From these viewpoints, the thickness of the conductive metal layer is preferably 20 to 500 nm and more preferably 20 to 350 nm.

From the viewpoints of uniformity of the film thickness and film-forming efficiency, the conductive metal layer is preferably formed by a vacuum film-forming method such as a chemical vapor deposition (CVD) method or a physical vapor deposition (PVD) method. Among these, physical vapor deposition methods such as a vacuum vapor deposition method, a sputtering method, an ion plating method, and an electron beam evaporation method are preferable, and a sputtering method is especially preferable.

### (Configuration of Film-Forming Apparatus)

The conductive metal layer 3 is formed while transporting the base by a roll-to-roll method. The film-forming process of the conductive metal layer by the roll-to-roll method is performed using a winding type vacuum film-forming apparatus 300 as schematically shown in FIG. 3. The vacuum film-forming apparatus 300 has the unwinding roll 301 and the winding roll 302, and a film-forming roll 310 and transporting rolls 303 and 304 in a film transport path between the unwinding roll 301 and the winding roll 302. A configuration is shown in FIG. 3 having one transporting roll 303 between the unwinding roll 301 and the film-forming roll 310 and one transporting roll 304 between the film-forming roll 310 and the winding roll 302. However, the vacuum film-forming apparatus 300 may have two or more transporting rolls. Each of the transporting rolls may be of a free rotation type or may be of a driving rotation type. From the viewpoint of controlling the transport tensile force in a region where the film is formed, at least one of the transporting rolls between the film-forming roll 310 and the winding roll 302 is preferably a driving rotation roll. The driving rotation roll may be arranged between the unwinding roll 301 and the film-forming roll 310. More preferably, at least one of the transporting rolls is a driving rotation roll in each of between the unwinding roll 301 and the film-forming roll 310 and between the film-forming roll 310 and the winding roll 302. The transport tensile force in a region where the film is formed refers to a tensile force between the film-forming roll and a driving roll that is the closest to the film-forming roll on the transport path of the film. The driving roll may be an independent driving rotation roll or a nip roll that sandwiches the film with two rolls as one pair.

From the viewpoint of controlling the tensile force in a region where the film is formed, the vacuum film-forming apparatus preferably has a tensile force detecting means such as a tension pickup roll or a dancer roll in the transport path. From the viewpoint of stabilizing the transportation of the film, a configuration having a tensile force control mechanism and in which the transport tensile force in a region where the film is formed can be controlled to be constant is preferable. The tensile force control mechanism is a mechanism that performs feedback so as to lower the peripheral speed of the driving rotation roll located on the downstream side of the transport path from the tensile force detecting means when the tensile force detected by the tensile force detecting means such as a tension pickup roll is larger than a set value and so as to raise the peripheral speed of the driving rotation roll large when the detected tensile force is smaller than the set value.

From the viewpoint of independently controlling the transport tensile force in a region where the film is formed and a film winding tensile force at the winding roll 302, a tension cut means is preferably provided in the film transport path between the film-forming roll 310 and the winding roll 302. From the viewpoint of independently controlling the transport tensile force in a region where the film is formed and an unwinding tensile force at the unwinding roll 301, a tension cut means is preferably provided in the film transport path between the unwinding roll 301 and the film-forming roll 310. A suction roll and a group of rolls that are arranged so that the film transport path comes to have an S-shape can be used as the tension cut means besides a nip roll. An appropriate tensile force detecting means such as a tension pickup roll is preferably arranged in the transport path between the tension cut means and the winding roll 302 to adjust the rotation torque of the winding roll 302 by the appropriate tensile force control mechanism so that the winding tensile force becomes constant. By independently controlling the transport tensile force in a region where the film is formed and the winding tensile force and/or the unwinding tensile force in such a manner, the generation of defects such as defective winding due to a small winding tensile force and blocking of the film due to a large winding tensile force can be suppressed.

The film-forming roll 310 is preferably configured so that the temperature thereof is adjustable. Examples of the means to adjust the temperature of the roll include a configuration in which a heating medium (and a coolant) can circulate inside of the roll, a configuration having a heating means such as an electric heater in the roll, and a configuration in which the surface of the roll can be heated from the outside of the roll by a heating means such as an infrared heater. A metal material source 320 such as a vapor deposition source or a sputtering target is installed near the film-forming roll, and metal atoms or molecules that are vaporized from this metal material source deposit on a base to form a film. When the conductive metal layer is formed by a CVD method, a material gas of an organic metal or the like is introduced into a reaction chamber instead of installation of the metal material source 320.

### (Conditions of Film Formation)

A base F including the transparent film base 1 and the transparent conductive layer 2 formed thereon is unwound from the unwinding roll 301 and is continuously transported via a plurality of transporting rolls 303 and 304 and the film-forming roll 310 while being prevented from loosening. The conductive laminated film 10 in which the conductive metal layer is formed by a vacuum film-forming process on the film-forming roll 310 is wound up by the winding roll 302. The transport tensile force per unit area in the plane perpendicular to the longitudinal direction of the film base in a region where the film is formed is preferably 0.6 to 1.8 N/mm², more preferably 0.7 to 1.7 N/mm², and further preferably 0.74 to 1.65 N/mm². By making the transport tensile force in the above-described range, the generation of wrinkles can be suppressed. Because the transportation of the film becomes unstable when the transport tensile force is too small, it is assumed that wrinkles are easily generated when the film meanders on the film-forming roll, for example. On the other hand, because shrinkage stress in the width direction of the film becomes large and adhesion strength of the film with the film-forming roll is large when the transport tensile force is too large, it is assumed that the film becomes difficult to slip on the roll and shrinkage deformation in the width direction causes wrinkles to be easily generated.

From the same viewpoints, the transport tensile force per unit width is preferably applied so as to satisfy the following formula:

0.6x≦y≦1.8x,

wherein x (mm) represents the thickness of the film base in a region where the film is formed and y (N/mm) represents the transport tensile force per unit width.

When the thickness of the film base is 50 μm (0.05 mm), the transport tensile force per unit width of the film base in a region where the film is formed is preferably 0.03 to 0.09 N/mm from the above formula, more preferably 0.04 to 0.08 N/mm, and further preferably 0.048 to 0.075 N/mm. When the thickness of the film base is 100 μm (0.1 mm), for example, the transport tensile force per unit width of the film base in a region where the film is formed is preferably 0.06 to 0.18 N/mm from the above formula, more preferably 0.08 to 0.17 N/mm, and further preferably 0.096 to 0.16 N/mm.

The temperature of the film-forming roll 310 when the conductive metal layer is formed is preferably 110 to 200° C., more preferably 120 to 180° C., and further preferably 130 to 155° C. When the temperature of the film-forming roll is too low, the difference in temperature between the surface where the film base contacts the film-forming roll and the surface where the film is formed becomes large. It is assumed that wrinkles are easily generated on the film because the temperature distribution in the thickness direction of the film becomes large. When the temperature of the film-forming roll is too high, it is assumed that wrinkles are easily generated because heat deformation of the film on the film-forming roll becomes large.

In general, the temperature of the base increases because energy of plasma, heating, and the like is supplied in order to promote vaporization and a vapor phase reaction of metals in the vacuum film-forming method, and heat deformation of the film base easily occurs. Because of that, in a conductive laminated film for a flexible printed wiring board in which the conductive metal layer of copper or the like is laminated on a heat resistant film base of polyimide or the like, a conductive metal layer is generally formed in a vacuum while cooling the base by the film-forming roll, thereby suppressing the generation of wrinkles. The present invention is based on a finding that, when the conductive metal layer 3 is further formed on a laminated film including the transparent film base 1 and the transparent conductive layer 2 formed thereon, wrinkles are easily generated when cooling is performed by the film-forming roll and conversely the generation of wrinkles is suppressed by heating the film by the film-forming roll.

It is not clear the reason why the tendency of the wrinkle generation differs between a case in which the conductive metal layer is formed directly on the film base as in the laminated film for a flexible printed wiring board and a case in which the conductive metal layer is formed on a film base including the transparent conductive layer as in the present invention. However, one of the causes is considered to be that the base is heated when the transparent conductive layer is formed and when the conductive metal layer is formed, respectively, that is, there is a thermal history difference in the base that is subjected to the formation of the conductive metal layer. Further, the conductive metal layer is generally formed on a heat resistant opaque film base such as a polyimide film in the metal laminated film for a flexible printed wiring board. The cause is also assumed to be related to the fact that the thermal deformation can be easily occur in the transparent film such as a polyester film because the thermal deformation temperature thereof is lower than that of the polyimide film and the like.

As described above, in the present invention, the generation of wrinkles can be suppressed by setting the temperature of the film-forming roll when the conductive metal layer 3 is formed and the transport tensile force in a region where the film is formed to be respectively in a prescribed range. Other conditions for forming a film are not especially limited as long as the temperature of the film-forming roll and the transport tensile force are respectively in the above-described range, and can be appropriately set according to the materials of the conductive metal layer 3, the film thickness, and the like.

When the conductive metal layer 3 made of copper is formed by a sputtering method, for example, it is preferred to use copper (preferably oxygen-free copper) as a target, and vent the sputtering machine to a degree of vacuum (ultimate vacuum) of preferably 1×10⁻³ Pa or less to create an atmosphere in which water in the sputtering machine and impurities such as an organic gas generated from the base have been removed.

An inert gas such as Ar is introduced in the vented sputtering machine and the temperature of the film-forming roll is adjusted to a temperature in the above-described range while transporting the base under application of a tensile force in the above-described range to form a film by sputtering under a reduced pressure. The pressure when the film is formed is preferably 0.05 to 1.0 Pa and more preferably 0.1 to 0.7 Pa. When the film-forming pressure is too high, the film-forming speed tends to decrease, and when the pressure is too low, discharge tends to become unstable.

In this way, the conductive laminated film in which the transparent conductive layer 2 and the conductive metal layer 3 are formed on the transparent film base 1 can be obtained. However, as shown in FIG. 2, a conductive laminated film 11 in which a second conductive metal layer 4 is further formed on the conductive metal layer 3 maybe formed. When the conductive metal layer 3 is made of copper, for example, the second conductive metal layer 4 can be formed on the copper layer as an anti-oxidation layer because copper is oxidized due to crystallization of the transparent conductive layer and a heating treatment when a device such as a touch panel is assembled, leading to an increase in the resistance value.

When the conductive metal layer 3 is made of copper, a film of a copper-nickel alloy can be formed as the second conductive metal layer 4 to serve as a good anti-oxidation layer. In this case, the second conductive metal layer preferably contains 15 to 55 parts by weight of nickel to 100 parts by weight of the total of copper and nickel. When the content of nickel is in this range, the layer can act as an anti-oxidation layer for copper, and a pattern wiring can be easily formed by etching because the etching treatment can be performed at the same time using the same etchant as an etchant for the conductive metal layer made of copper.

The thickness of the second conductive metal layer 4 is 5 to 100 nm, for example. When the thickness of the second conductive metal layer is too small, an action as an anti-oxidation layer cannot be exhibited, and when the thickness of the second conductive metal layer is too large, productivity becomes poor because long time is required to form the film and heat wrinkles tend to be easily generated.

<Transparent Conductive Laminated Film with Pattern Wiring>

The conductive laminated film of the present invention is suitable for forming a transparent conductive laminated film with a pattern wiring. FIG. 4 is a schematic plan view of a transparent conductive laminated film with a pattern wiring of one embodiment, and FIG. 5 is a drawing schematically showing a section at the V-V line of FIG. 4. A transparent conductive laminated film 100 with a pattern wiring has a transparent electrode part consisting of a plurality of transparent electrodes 121 to 126 and pattern wiring parts 131a to 136a and 131b to 136b. The pattern wirings are connected to the transparent electrodes. The transparent conductive layer is patterned so as to form the plurality of transparent electrodes 121 to 126 in FIG. 4. However, the transparent conductive layer does not have to be patterned. Each of the transparent electrodes is patterned into a strip shape and both ends thereof are connected to a pattern wiring in FIG. 4. However, the shape of the electrode is not limited to a strip shape, and the transparent electrode may be connected to the pattern wiring at one place or three or more places. Each pattern wiring is connected to a control means 150 such as an IC as necessary.

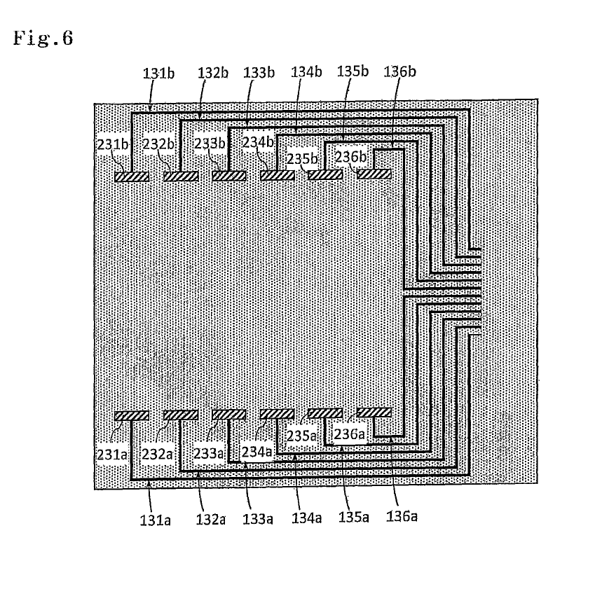

As schematically shown in FIG. 6, a transparent electrode 121 is a region having the transparent conductive layer 2 on the transparent film base 1, and the pattern wirings 131a and 131b are regions having the transparent conductive layer 2 and the conductive metal layer 3 in this order on the transparent film base 1. Additional layers such as the second conductive metal layer as described above may be formed on the conductive metal layer 3.

The transparent conductive laminated film with a pattern wiring can be formed by patterning each of the transparent conductive layer 2 and the conductive metal layer 3 of the conductive laminated film by etching or the like. Specifically, a portion of the conductive metal layer 3 is removed to form a pattern wiring. At this time, a process is performed so that the conductive metal layer 3 remains on the pattern wiring parts 131a to 136a and 131b to 136b. When a second conductive metal layer is formed on the conductive metal layer 3, the second conductive metal layer is preferably patterned in the same manner by etching or the like. The process is also preferably performed so that the conductive metal layer 3 remains on connection parts 231a to 236a and 231b to 236b of the transparent electrodes and the pattern wirings. The connection parts of the pattern wirings and the transparent electrodes configure a portion of the pattern wiring part.

The conductive metal layer is preferably removed by etching. In etching, it is preferred to use a method in which the surface of the region that corresponds to the pattern wiring part and the connection part is covered with a mask for forming a pattern to etch the conductive metal layer 3 with an etchant. When the second conductive metal layer is further formed on the conductive metal layer 3, the second conductive metal layer is preferably removed by etching at the same time together with the conductive metal layer 3.

The conductive metal layer 3 is removed, and then a portion of the transparent conductive layer 2 is removed in an exposed portion of the transparent conductive layer 2 to form the patterned transparent electrodes 121 to 126 as shown in FIG. 4. The transparent conductive layer 2 is also preferably removed by etching. Upon etching, a method is preferably used in which the surface of the regions that correspond to the transparent electrode parts 121 to 126 is covered with a mask for forming a pattern to etch the transparent conductive layer 2 with an etchant.

The etchant used in etching of the transparent conductive layer can be appropriately selected according to the material that forms the transparent conductive layer. When a conductive oxide such as ITO is used for the transparent conductive layer, an acid is preferably sued as an etchant. Examples of the acid include inorganic acids such as hydrogen chloride, hydrogen bromide, sulfuric acid, nitric acid, and phosphoric acid, organic acids such as acetic acid, mixtures of these, and aqueous solutions of these.

### <Optical Device>

The transparent conductive laminated film with a pattern wiring obtained in such a manner is provided with the control means 150 such as an IC as necessary and is put to practical use. Because the transparent conductive laminated film has patterned transparent electrodes and each of the transparent electrodes is connected to a pattern wiring, the film is suitably used in various optical devices. Examples of the device include a touch panel, flat panel displays such as a liquid crystal display, a plasma display, and an organic EL display, and a lighting system. Examples of the touch panel include a capacitance type touch panel and a resistive film type touch panel.

When such an optical device is formed, the transparent conductive laminated film with a pattern wiring may be used as it is or additional layers may be provided on the transparent electrodes. For example, in the case of an organic EL display, a light emitting layer, a metal electrode layer that can act as a cathode, or the like can be provided on the transparent electrode that can act as an anode.

### EXAMPLE

The method of manufacturing a conductive laminated film of the present invention is explained in detail by way of an example below. However, the present invention is not limited to the example as long as it is within the scope of its purpose.

### (Formation of Dielectric Layer)

A solution obtained by diluting silica sol (Colcoat P manufactured by Colcoat Co., Ltd.) with ethanol so as to have the solid content concentration of 2% was applied to one surface of a transparent film of a biaxially stretched polyethylene terephthalate film (product name: T602E50 manufactured by Mitsubishi Plastics, Inc., Tg: 69° C., sectional area: 54.25 mm², referred to as a PET film below) having a width of 1085 mm and a thickness of 50 μm (0.05 mm) by a silica coating method, and the coated film was dried at 150° C. for 2 minutes to cure to form a dielectric layer (a SiO₂ film, refractive index of light: 1.46) having a thickness of 35 nm.

### (Formation of Transparent Conductive Layer)

A sintered body target containing indium oxide and tin oxide at a weight ratio of 90:10 was installed in a parallel plate winding type magnetron sputtering machine as schematically shown in FIG. 3. Dehydration and degassing were performed by venting the machine to vacuum while transporting the PET film base on which the dielectric layer had been formed. Then, the temperature of the film-forming roll was set to 140 to 145° C., an argon gas and an oxygen gas were introduced, and an ITO film having a thickness of 25 nm was formed on the dielectric layer by performing DC sputtering while transporting the base at a transport speed of 7.7 m/min and a transport tensile force of 0.036 to 0.11 N/mm to form a transparent conductive film. The surface resistance of the ITO film on the surface of the transparent conductive film was 450 Ω/□ upon measurement by a four probe method.

### (Formation of Conductive Metal Layer)

An oxygen free copper target was installed in a parallel plate winding type magnetron sputtering machine as schematically shown in FIG. 3. Dehydration and degassing were performed by venting the machine to vacuum while transporting the transparent conductive film including the base and the ITO film formed thereon. Then, an argon gas was introduced, and DC sputtering was performed while transporting the base at a transport speed of 4.4 m/min to form a conductive metal layer having a thickness of 80 nm made of copper on the ITO film. The transport tensile force per unit area in the plane perpendicular to the longitudinal direction of the PET film in forming the conductive metal layer was changed in the range of 0.56 to 2.22 N/mm² (the transport tensile force per unit width was changed in the range to 0.028 to 0.11 N/mm) and the temperature of the film-forming roll was changed in the range of 80 to 220° C. to evaluate the conductive laminated film of each level. In any of the levels, the surface resistance of the metal layer measured by the four probe method was 0.3 Ω/□.

### (Evaluation of Heat Wrinkles)

The conductive laminated film obtained in each level was cut into a length of about 15 cm in the transporting direction, and was illuminated with a fluorescent light to visually confirm presence or absence of heat wrinkles.

A No heat wrinkles were observed.

B A small amount of heat wrinkles were observed.

C A large amount of heat wrinkles were observed.

The transport tensile force (N/mm²) per unit area of the film base at each film-forming roll temperature in forming the conductive metal layer and the evaluation result of the heat wrinkles are shown in Table 1. The transport tensile force (N/mm) per unit width of the film base and the evaluation result of the heat wrinkles are shown in Table 2.

TABLE 1

| | | Film-forming roll temperature (° C.) | | | | | | | | |
|---|---|---|---|---|---|---|---|---|---|---|
| | | 90 | 100 | 110 | 120 | 140 | 150 | 170 | 200 | 220 |
| Transport | 0.56 | C | C | C | C | C | C | C | C | C |
| tensile | 0.74 | C | C | A | A | A | A | A | A | C |
| force per | 1.12 | C | C | A | A | A | A | A | A | C |
| unit | 1.3 | C | C | A | A | A | A | A | A | C |
| area | 1.48 | C | C | A | A | A | A | A | A | C |
| (N/mm²) | 1.64 | C | C | A | A | A | A | A | A | C |
| | 1.84 | C | C | C | B | B | B | B | B | C |
| | 2.22 | C | C | C | C | C | C | C | C | C |

TABLE 2

| | | Film-forming roll temperature (° C.) | | | | | | | | |
|---|---|---|---|---|---|---|---|---|---|---|
| | | 90 | 100 | 110 | 120 | 140 | 150 | 170 | 200 | 220 |
| Transport | 0.028 | C | C | C | C | C | C | C | C | C |
| tensile | 0.037 | C | C | A | A | A | A | A | A | C |
| force per | 0.056 | C | C | A | A | A | A | A | A | C |
| unit | 0.065 | C | C | A | A | A | A | A | A | C |
| width | 0.074 | C | C | A | A | A | A | A | A | C |
| (N/mm) | 0.082 | C | C | A | A | A | A | A | A | C |
| | 0.092 | C | C | C | B | B | B | B | B | C |
| | 0.111 | C | C | C | C | C | C | C | C | C |

As shown in Tables 1 and 2, the generation of wrinkles was suppressed by setting the film-forming roll temperature and the film transport tensile force in forming the conductive metal layer to prescribed ranges.

Additionally, the heat wrinkles were evaluated on the conductive laminated film using a PET film (sectional area: 136.25 mm²) having a width of 1090 mm and a thickness of 125 μm as the film base at a film-forming roll temperature of 140° C. and a transport tensile force per unit area of the film base of 0.73 N/mm² (the transport tensile force per unit width was 0.092 N/mm). The evaluation result was “A,” and the generation of wrinkles was suppressed.

Similarly, the heat wrinkles were evaluated on the conductive laminated film using a PET film (sectional area: 136.25 mm²) having a width of 1090 mm and a thickness of 125 μm as the film base at a film-forming roll temperature of 140° C. and a transport tensile force per unit area of the film base of 1.17 N/mm² (the transport tensile force per unit width was 0.147 N/mm). The evaluation result was “A,” and the generation of wrinkles was suppressed.

Next, the heat wrinkles were evaluated on the conductive laminated film using a PET film (sectional area: 109 mm²) having a width of 1090 mm and a thickness of 100 μm as the film base at a film-forming roll temperature of 140° C. and a transport tensile force per unit area of the film base of 1.47 N/mm² (the transport tensile force per unit width was 0.147 N/mm). The evaluation result was “A,” and the generation of wrinkles was suppressed.

### EXPLANATION OF THE REFERENCE NUMERALS

1 TRANSPARENT FILM BASE
2 TRANSPARENT CONDUCTIVE LAYER
3 CONDUCTIVE METAL LAYER
4 SECOND CONDUCTIVE METAL LAYER
10, 11 CONDUCTIVE LAMINATED FILM
300 WINDING TYPE SPUTTERING MACHINE
301 UNWINDING ROLL
302 WINDING ROLL
303 TRANSPORTING ROLL
310 FILM-FORMING ROLL
320 METAL MATERIAL SOURCE
100 TRANSPARENT CONDUCTIVE LAMINATED FILM WITH PATTERN WIRING
121 TO 126 TRANSPARENT ELECTRODES
131 TO 136 PATTERN WIRINGS
150 CONTROL MEANS
231 TO 236 CONNECTION PARTS

What is claimed is:

1. A method of manufacturing a long conductive laminated film comprising the steps of:
preparing a long transparent conductive film including a long transparent film base containing a polyester resin as a constituting material and a transparent conductive layer formed thereon; and
continuously forming a conductive metal layer on a surface of the long transparent conductive film where the transparent conductive layer is formed while transporting the long transparent conductive film,
wherein
the metal layer forming step is performed under a reduced pressure atmosphere of 1 Pa or less,
the long transparent conductive film is continuously transported by application of a transport tensile force in the metal layer forming step,
the conductive metal layer is continuously deposited on the surface where the transparent conductive layer is formed in a state in which a surface of the transparent conductive film where the transparent conductive layer is not formed contacts the surface of a film-forming roll,
the surface temperature of the film-forming roll is 110 to 200° C., and
the transport tensile force per unit area in a plane perpendicular to the longitudinal direction of the film base in a region where the film is formed is 0.6 to 1.8 N/mm².

2. The method of manufacturing a conductive laminated film according to claim 1, wherein a transport tensile force per unit width is applied so as to satisfy the following formula wherein x (mm) represents the thickness of the film base in a region where the film is formed and y (N/mm) represents the transport tensile force per unit width:
0.6x≦y≦1.8x.

3. The method of manufacturing a conductive laminated film according to claim 1, wherein the metal layer is formed by a sputtering method in the metal layer forming step.

4. The method of manufacturing a conductive laminated film according to claim 1, wherein the deposition thickness of the conductive metal layer is 20 nm or more.

5. The method of manufacturing a conductive laminated film according to claim 1, wherein the transparent conductive layer is a conductive oxide layer containing an indium-tin oxide as a main component.

6. The method of manufacturing a conductive laminated film according to claim 1, wherein the conductive metal layer is made of one type or two types or more of metals selected from the group consisting of Ti, Si, Nb, In, Zn, Sn, Au, Ag, Cu, Al, Co, Cr, Ni, Pb, Pd, Pt, W, Zr, Ta, and Hf or an alloy containing these metals as a main component.
